(19) United States
(12) Patent Application Publication
(10) Pub. No.: US 2021/0079514 A1
(43) Pub. Date: Mar. 18, 2021

(54) Sputtering Method and Sputtering Apparatus

(71) Applicant: ULVAC, INC., Kanagawa (JP)

(72) Inventors: Yoshinori Fujii, Kanagawa (JP); Shinya Nakamura, Kanagawa (JP); Mitsunori Noro, Kanagawa (JP); Kazuyoshi Hashimoto, Kanagawa (JP)

(73) Assignee: ULVAC, INC., Kanagawa (JP)

(21) Appl. No.: 16/954,441

(22) PCT Filed: Dec. 4, 2018
(86) PCT No.: PCT/JP2018/044509

§ 371 Date: Jun. 16, 2020

(30) Foreign Application Priority Data
Dec. 27, 2017 (JP) 2017-251342

(51) Int. Cl. C23C 14/34; C23C 14/06

(52) U.S. Cl. CPC C23C 14/34; C23C 14/0605

(57) ABSTRACT

[SUMMARY] A sputtering method includes disposing a carbon target (Tg) and a film-forming object (Wf) inside a vacuum chamber (1); evacuating the vacuum chamber to a predetermined pressure by a vacuum pump (Vp); subsequently introducing a sputtering gas into the vacuum chamber; charging the target with electric power to form a plasma atmosphere such that the target gets sputtered by the ions of the sputtering gas in the plasma, whereby carbon particles splashed from the target are caused to be adhered to, and deposited on, a surface of the film-forming object, thereby forming a carbon film. The target is cooled by heat exchanging with a first refrigerant at least during the time when the target receives radiant heat from the plasma; wherein the temperature of the first refrigerant is controlled to keep the temperature of the first refrigerant below 263K.

### TECHNICAL FIELD

The present invention relates to a sputtering method and a sputtering apparatus for forming a carbon film on a surface of an objet on which a film is formed (also called as a “film-forming object”).

### BACKGROUND ART

Conventionally, there is a case in which a carbon film is used as an electrode film of a device such as a nonvolatile memory and the like. In the film formation of this kind of carbon films, a sputtering apparatus using a carbon target is generally utilized (for example, see patent document 1). This kind of sputtering apparatus is ordinarily provided with: a vacuum chamber having a carbon target; a stage which holds, inside the vacuum chamber, a substrate as a film-forming object in a posture of lying opposite to the target; a deposition-preventive plate enclosing a space between the target and the stage; a gas introduction means for introducing a sputtering gas, inclusive of a rare gas, into the vacuum chamber in a vacuum atmosphere; and an electric power supply for charging the target with electric power.

In forming a carbon film with the above-mentioned sputtering apparatus: a substrate is set in position on the stage; after having evacuated the vacuum chamber, by a vacuum pump, to a predetermined pressure, the sputtering gas is introduced at a predetermined flow rate by the gas introduction means; the target is charged with electric power to thereby form a plasma atmosphere inside the vacuum chamber; the target gets sputtered by the ions of the sputtering gas in the plasma, thereby causing the carbon particles scattered from the target to get adhered to, and deposited on, the surface of the film-forming object to form a carbon film. While the target is sputtered, the target gets heated by the radiation heat from the plasma. Therefore, the target is cooled, by heat exchanging with a refrigerant, below a predetermined temperature at least during the time when electric power is charged to the target.

By the way, when a carbon target is sputtered to form a film on the surface of the substrate, there are cases where fine particles will be adhered to the surface of the substrate that has just finished forming a film thereon. Since this kind of adhesion of the particles will be a cause for lowering in the availability percentage of the product, it is necessary to restrain, to the best (i.e., to the minimum) extent possible, the adhesion of the particles to the surface of the film-forming object.

Then, as a result of diligent studies, the inventors of this invention have obtained a finding that: the fine particles are carbon particles that are kept suspended within the vacuum chamber; and that this kind of carbon particles (that are different from those splashed, by sputtering, from the sputtered surface of the target) are ejected also from the surface of the target during the film formation or just after the film has been formed thereon, so that they are kept suspended inside the vacuum chamber. In other words, as the carbon targets there are used pyrocarbon targets or amorphous carbon targets. Especially, since the pyrocarbon targets have a laminated structure, thermal conduction in the direction of lamination is good, but the thermal conduction along those surfaces of the target which lie perpendicular to the direction of lamination is considerably bad. Such being the case, carbon particles are estimated to be ejected from the target due to the difference when the target is thermally expanded by being heated with the radiation heat from the plasma. In this case, although it has been confirmed that the smaller the charged electric power is made at the time of sputtering (i.e., the lower the surface temperature of the target is made during film formation), the smaller becomes the amount of the fine particles to be adhered to the surface of the film-forming object just after the film has been formed thereon. This solution, however, will give rise to the problem that the productivity lowers.

### PRIOR ART DOCUMENTS

### Patent Documents

Patent Document 1: International Publication No. 2015/122159

### SUMMARY OF THE INVENTION

### Problems that the Invention is to Solve

This invention has been made based on the above-mentioned finding and has an object of providing a sputtering method and a sputtering apparatus which are capable of restraining, to the best extent possible, the number of fine particles that will be adhered to the surface of the substrate just after the film has been formed thereon.

### Means for Solving the Problems

In order to solve the above-mentioned problem, this invention is a sputtering method of forming a carbon film, comprising: disposing a carbon target and a film-forming object inside a vacuum chamber; evacuating the vacuum chamber to a predetermined pressure by a vacuum pump; subsequently introducing a sputtering gas into the vacuum chamber; charging the target with electric power to form a plasma atmosphere such that the target gets sputtered by the ions of the sputtering gas in the plasma, whereby carbon particles splashed from the target are caused to be adhered to, and deposited on, a surface of the film-forming object, thereby forming a carbon film, wherein the target is cooled by heat exchanging with a first refrigerant at least during the time when the target receives radiant heat from the plasma such that the temperature of the first refrigerant is controlled to keep the temperature of the first refrigerant below 263K.

According to this invention, if the temperature of the first refrigerant is kept below 263K at least during the time when the target receives radiant heat from the plasma, the number of fine particles that will be adhered to the surface of the substrate as a film-forming object just after the film has been formed thereon can be restrained to the best (i.e., to the minimum) extent possible without particularly lowering the electric power to be charged to the target. This art has been confirmed to be particularly effective when the pyrocarbon target is used as the carbon target. For reference' purpose, it is to be noted that if the temperature of the first refrigerant is above 263K, the number of fine particles to be adhered to the surface of the substrate that has just finished film forming thereon cannot be restrained effectively. On the other hand, even if the temperature of the first refrigerant is made below 263K, it has been confirmed through experiments that the number of fine particles to be adhered to the surface of the substrate shows little or no changes.

Some sputtering apparatuses employ direct cooling of the target, at the time of sputtering, by circulating the refrigerant through a rear surface of the carbon target, and others employ indirect cooling of the target, in which the carbon target is bonded in advance to the backing plate, the cooling being performed by circulating the refrigerant through the backing plate. In either of the above examples, except for the time during sputtering (at the time of being heated by radiant heat from the plasma), the surface temperature of the target becomes equivalent to the temperature of the first refrigerant. Then, at the time of sputtering (at the time when radiant heat is received from the plasma), the surface temperature of the target is substantially kept at a predetermined temperature that is substantially proportional to the temperature of the first refrigerant. Therefore, by controlling the temperature of the first refrigerant, the emission into the vacuum chamber of the carbon fine particles from the surface of the target due to the thermal expansion of the target as a result of radiant heat from the plasma can be restrained to the best extent possible. By the way, if an arrangement is made that, even at the time other than sputtering (in particular, during replacement of substrates at the time of film-forming processing of a plurality of substrates), the target can be cooled by supplying the first refrigerant, the carbon particles that are kept in suspension inside the vacuum chamber can advantageously be adhered to, and held by, the target just after the film has been formed thereon (just after having stopped the electric charging to the target).

By the way, in case the carbon target is sputtered, the carbon particles scattered from the target will get adhered, not only to the film-forming object, but also get adhered to, and deposited on, various kinds of such parts present inside the vacuum chamber as anode rings, deposition-preventive plates, etc. Then, these adhered carbon particles may sometimes be released again for some unknown causes, thereby remaining suspended inside the vacuum chamber. Since these carbon particles may also form fine particles to thereby adhere on that surface of the substrate which has just finished formation of a film thereon, it is necessary to restrain this possibility to the best extent possible. As a possible solution, it is proposed: to dispose inside the vacuum chamber a cooling body cooled by the second refrigerant; to cause the carbon particles kept suspended inside the vacuum chamber to be adsorbed on an adsorbent, thereby reducing the number of carbon particles kept suspended in the vacuum chamber. However, as described above, in case the target is cooled by heat exchanging with the first refrigerant, depending on the temperature of the cooling body and further depending on the temperature of the second refrigerant, it has been found that the number of fine particles to be adhered to the surface of the substrate that has just finished forming a film thereon, does increase contrary to the expectations.

In this invention, control shall preferably be made to keep the temperature of the second refrigerant at a temperature within a range of 123K and 325K or to keep the sum of the temperature of the first refrigerant to be supplied to the target and the temperature of the second refrigerant to be supplied to the cooling body at a temperature within a range of 370K and 590K. As a result of the above arrangement, the number of fine particles to get adhered to the surface of the substrate that has just finished forming a film thereon can further be restrained. By the way, the above-mentioned cooling body may be constituted by a cooling panel which encloses a space between the target and the film-forming object, both being disposed to lie opposite to each other, the cooling panel being disposed in close proximity, from an outside of the space, to the deposition-preventive plate. By the way, if the sum of the first refrigerant and the second refrigerant is below 370K or above 590K, it has been confirmed as a result of experiments that the number of the fine particles that will be adhered to the surface of the substrate on which the film has just been formed, will increase contrary to the expectations. In addition, in case the temperature of the second refrigerant is below 123K or above 325K, it has similarly been confirmed as a result of experiments that the number of the fine particles that will be adhered to the surface of the substrate on which the film has just been formed, will increase contrary to the expectations.

In addition, in order to solve the above-mentioned problem, this invention is a sputtering apparatus comprising: a vacuum chamber having a carbon target; a stage for holding, inside the vacuum chamber, a film-forming object in a posture to lie opposite to the target; a deposition-preventive plate for enclosing a space between the target and the stage; a gas introduction means for introducing a sputtering gas into the vacuum chamber in a vacuum atmosphere; a power supply for charging the target with electric power; and a first refrigerant supply means for supplying the first refrigerant to keep the target at a predetermined temperature by heat exchanging with the first refrigerant at least during the time when the target receives radiant heat from a plasma; wherein the first refrigerant supply means controls the temperature of the first refrigerant to keep the temperature of the first refrigerant below 263K. In this case, preferably the sputtering apparatus further comprises: a cooling panel disposed, from an outside of the space, close to the deposition-preventive plate; and a second refrigerant supply means for supplying the cooling panel with a second refrigerant, wherein the second refrigerant supply means controls the temperature of the second refrigerant to a temperature within a range of 123K and 325K. In addition, the sputtering apparatus preferably further comprises: a temperature control means for controlling the temperature such that a sum of the temperature of the first refrigerant and the temperature of the second refrigerant becomes a temperature of a range of 370K and 590K.

### BRIEF DESCRIPTION OF THE DRAWINGS

FIG. 1 is a sectional view schematically showing the sputtering apparatus of an embodiment of this invention.

FIG. 2 is a graph showing the results of experiments to confirm the effects of this invention.

FIG. 3(a) and FIG. 3(b) are graphs showing the results of experiments to confirm the effects of this invention.

### MODES FOR CARRYING OUT THE INVENTION

Hereinbelow, with reference to the drawings, a description will now be made of an embodiment of a sputtering method and a sputtering apparatus according to this invention taking an example in which, provided that the film-forming object is defined as a silicon wafer (hereinafter referred to as “substrate Wf”), a carbon target is defined as a pyrocarbon target (hereinafter referred to as “target Tg”), a target Tg is mounted on an upper portion of a vacuum chamber in a state in which the target Tg is bonded to a backing plate Bp.

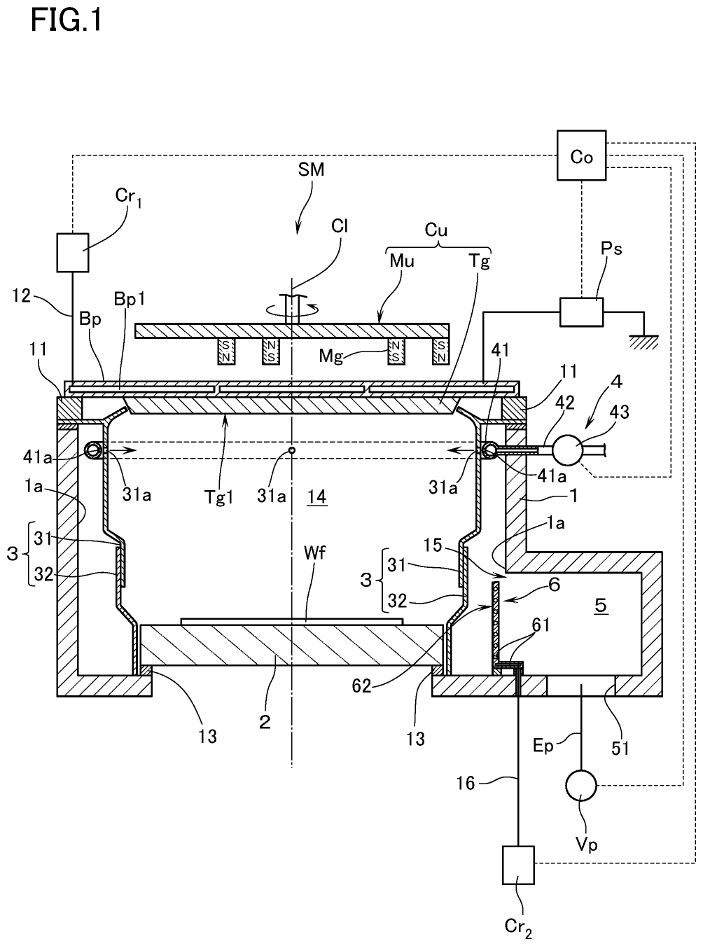

With reference to FIG. 1, reference mark SM denotes a magnetron type sputtering apparatus according to the embodiment of this invention. The sputtering apparatus SM is provided with a vacuum chamber 1, and a cathode unit Cu is detachably mounted on an upper part of the vacuum chamber 1. The cathode unit Cu has a target Tg, and a magnet unit Mu which is disposed above the target Tg so as to operate a leakage magnetic field penetrating through the target Tg. The target Tg is formed in a laminated structure by a known method and has a circular profile depending on the profile of the substrate Wf. Further, the target Tg is bonded, through a known bonding agent, to a lower surface of a backing plate Bp which is made of a metal superior in thermal conduction such as copper and the like and which has formed inside thereof a refrigerant circulation passage Bp1. In this state with the sputtering surface Tg1 facing downward, the target Tg is mounted on an upper portion of the vacuum chamber 1 through an electrically insulating body 11 that is disposed on an upper wall of the vacuum chamber 1.

To the inlet and outlet (not illustrated) of the refrigerant circulation passage Bp1 of the backing plate Bp, there is connected a piping 12 from a first chiller unit Cr₁ as the first refrigerant supply means. When a film is formed on the surface of the substrate Wf by sputtering the target Tg, or when the sputtering of the target Tg is stopped to replace the substrate Wf on which a film is going to be formed, the refrigerant is circulated through the refrigerant circulation passage Bp1 of the backing plate Bp, so that the target Tg can be cooled to a predetermined temperature. As the refrigerant, as long as it is in a liquid phase at the atmospheric pressure, there is no particular limitation. Alcohols such as ethylene glycol and the like, or fluorine base inert fluids are used. As the chiller unit Cr₁ there may be used one of a known construction. In this embodiment it is so arranged that the temperature of the first refrigerant can be kept below 263K at the inlet of the refrigerant circulation passage Bp1. In this case, if the temperature of the first refrigerant is above 263K, there is a possibility that the number of fine particles to be adhered to the surface of the substrate just after a film has been formed thereon cannot effectively be restrained, on the one hand, and even if the temperature of the first refrigerant is made below 263K, there is little or no change in the number of fine particles that are adhered to the surface of the substrate just after a film has been formed thereon.

The backing plate Bp has connected thereto a sputtering power supply Ps so that, at the time of film formation by sputtering, DC power having negative electric potential can be charged to the target Tg through the backing plate Bp. In addition, the magnet unit Mu which is disposed above the target Tg is, though not explained by particularly illustrating, provided with a plurality of magnet pieces Mg with a different magnetic pole on the side of the sputtering surface Tg1 of the target Tg, i.e., of a closed magnetic field or cusp magnetic field construction in which a leakage magnetic field is caused to be operated in the lower space of the target Tg. By the way, as the magnet unit itself, a known type may be utilized and, therefore, no further explanation will be made inclusive of the rotary mechanism thereof and the like.

Further, at the central bottom portion of the vacuum chamber 1, there is disposed a stage 2 in a manner to lie opposite to the target Tg. Although not explained by particularly illustrating, the stage 2 is constituted by a metallic base having, e.g., a cylindrical profile, and a chuck plate which is bonded to the upper surface of the base. It is thus so arranged that, during film formation, the substrate Wf can be held in position by suction. By the way, as to the construction of the electrostatic chuck, there may be utilized known ones such as of a single pole type, a bipolar type, and the like. Therefore, further detailed explanations will be omitted. In this case, it may be so arranged that the base has contained therein a passage for the refrigerant circulation, and a heater so that, during film formation, the substrate Wf can be controlled to a predetermined temperature.

Inside the vacuum chamber 1 there is disposed, at a space from the inside wall, a deposition-preventive plate 3 which encloses a film-forming space 14 between the target Tg and the stage 2. The deposition-preventive plate 3 has: a cylindrical upper plate portion 31 which encloses the circumference of the target Tg and which is also elongated downward of the vacuum chamber 1; and a cylindrical lower plate portion 32 which is elongated therefrom upward of the vacuum chamber 1. It is so arranged that the lower end of the upper plate portion 31 and the upper end of the lower plate portion 32 are overlapped with each other with a circumferential clearance therebetween. By the way, the upper plate portion 31 and the lower plate portion 32 may also be formed integrally with each other, or may be circumferentially divided into a plurality of portions and are then combined together.

The vacuum chamber 1 is provided with a gas introduction means 4 for introducing a sputtering gas which is a rare gas (inclusive of a reactant gas such as oxygen gas, nitrogen gas, and the like to be appropriately introduced depending on the necessity). The gas introduction means 4 has a gas ring 41 disposed along an outer periphery of the upper part 31, and a gas pipe 42 which is connected to the gas ring 41 and which penetrates through the side wall of the vacuum chamber 1. The gas pipe 42 is in communication with a gas source (not illustrated) through a mass flow controller 43. The gas ring 41 is so arranged that an equivalent amount of sputtering gas is injected out of gas injection ports 41a that are bored at an equal distance along the circumferential direction. The sputtering gas that has been ejected out of the gas ejection ports 41a is introduced at a predetermined flow rate, from the gas holes 31a formed in the upper plate portion 31, into the film-forming space 14 to be defined by the target Tg, the stage 2, and the deposition-preventive plate 3. During the film formation, the pressure distribution inside the film-forming space 14 is arranged to be made equal over the entire film-forming space 14.

The vacuum chamber 1 is provided with an exhaust space part 5 which is locally expanded in the direction perpendicular to the center line C1 passing through the center of the target Tg. The bottom wall surface that defines this exhaust space part 5 has opened an exhaust port 51 and this exhaust port 51 has connected thereto, through an exhaust pipe Ep, a vacuum pump Vp such as a cryopump, a turbo molecular pump, and the like. Then, the sputtering gas that was introduced into the film-forming space 14 at the time of film formation partly becomes exhaust gas so as to flow from the joints of the deposition-preventive plate 3, and from the clearance between the deposition-preventive plate 3 and the target Tg and the stage 2, through the clearance between the outside surface of the deposition-preventive plate 3 and the inside wall surface of the vacuum chamber 1, thereby flowing from the exhaust gas inlet 15 as a boundary between the vacuum chamber 1 and the exhaust space part 5 into the exhaust space part 5 and is vacuum-evacuated through the exhaust port 51 into the vacuum pump Vp. At this time, between the film-forming space 14 and the exhaust space part 5, there will be generated a pressure difference of about several Pa.

In a position of the border between the film-forming space 14 and the exhaust space part 5, there is disposed a cooling panel 6 inside the vacuum chamber 1. The cooling panel 6 is made of metal such as copper and the like which is superior in thermal conduction, and which has formed inside thereof a refrigerant circulation passage 61. The panel surface 62 is curved so as to have an equivalent curvature as the lower plate part 32, and is disposed so as to lie opposite to the lower plate part 32 at a clearance therebetween. The inlet and the outlet (not illustrated) of the refrigerant circulation passage 61 of the cooling panel 6 have connected thereto a pipe 16 from the second chiller unit Cr₂ as the second refrigerant supply means. At the time of sputtering the target Tg to form a film on the surface of the bsubstrate Wf or at the time of having stopped the sputtering of the target Tg so that a substrate Wf on which a film is going to be formed is replaced for another, the second refrigerant is circulated through the refrigerant circulation passage 61 to cool the cooling panel 6 and consequently the deposition-preventive plate 3 down to a predetermined temperature. In this embodiment, the deposition-preventive plate 3 to be cooled by the cooling panel 6 constitutes the cooling body that is arranged inside the vacuum chamber 1. As the refrigerant, in the same manner as the above, there is no particular limitation as long as it is in the liquid phase at the atmospheric pressure; known alcohols such as ethylene glycol and the like, or fluorine base inert fluid are used. As the second chiller unit Cr₂, there may be utilized known ones. In this embodiment, an arrangement was made that the temperature of the second refrigerant is kept at a range of temperature of 50K and 350K at the inlet of the refrigerant circulation passage 61. Taking into consideration the temperature of the first refrigerant, the sum of the temperature of the first refrigerant and the temperature of the second refrigerant is arranged to be controlled within a range of temperature of 370K and 590K. By the way, in this embodiment, a description was made of an example in which the cooling panel 6 is disposed so as to lie opposite to the lower plate part 32. However, as long as the deposition-preventive plate 3 can be kept at a predetermined temperature over its entirety during sputtering or at the time before or after the sputtering, its mode shall be free.

In addition, the sputtering apparatus SM is provided with a regulation controller Co of a known construction and which is provided with a microcomputer, memory cells, sequensers, and the like. This regulation controller Co performs an overall control over each of the parts at the time of film formation by sputtering, the control being made of the vacuum pump Vp, mass flow controller 43 of the gas introduction means 4, sputtering power supply Ps, and the like. In this embodiment, the controllet Co serves the dual purpose of a temperature control means which also controls the operation of the first and the second chiller units Cr₁, Cr₂ so that the sum of the temperatures of the first refrigerant and the second refrigerant can be controlled to a range of temperature of 370K and 590K. A description will hereinbelow be made in concrete of the sputtering method of this invention with reference to an example in which a carbon film is formed on a substrate Wf by the above-mentioned sputtering apparatus SM.

First, by means of a vacuum transfer robot (not illustrated), a substrate Wf is transferred and placed in position on the stage 2, and the substrate Wf is sucked for holding with a chuck plate of the stage 2 (the upper surface of the substrate Wf is the surface on which a film is formed, i.e., “film-forming surface”). At this time, the regulation controller Co respectively circulates the first refrigerant and the second refrigerant by both the first and the second chiller units Cr₁, Cr₂ so that the supply temperature of the first refrigerant to the target Tg is at a predetermined temperature below 263K and also the sum of the temperatures of the first refrigerant and the second refrigerant is controlled to a temperature of a range of 370K and 590K. Then, when the inside of the vacuum chamber 1 has been evacuated down to a predetermined pressure (e.g., 1×10⁻⁵ Pa), the sputtering gas (argon gas) is introduced at a predetermined flow rate through the gas introduction means 4, and the target Tg is charged with a predetermined electric power (of a range of 0.5 and 10 kW) having a negative electric potential. According to these operations, a plasma atmosphere is formed inside the film-forming space 14, and the target Tg gets sputtered by the ions of the sputtering gas in the plasma. The sputtered particles from the target Tg will be adhered to, and deposited on, the film-forming surface of the substrate Wf, thereby forming a carbon film.

It is to be noted here that, before starting the sputtering, the surface temperature of the target Tg becomes equivalent to the temperature of the first refrigerant, and the panel surface 62 of the cooling panel 6 becomes equivalent to the temperature of the second refrigerant. Then, at the time of sputtering (when radiant heat is received from the plasma) the target Tg will be heated by the radiant heat from the plasma, but the surface temperature of the target Tg comes to be kept at a predetermined temperature substantially proportional to the temperature of the first refrigerant, and the surface temperature of the deposition-preventive plate 3 comes to be kept at a predetermined temperature substantially proportional to the temperature of the second refrigerant, respectively. Once the film formation of the carbon film on the substrate Wf has been finished, the introduction of the sputtering gas and the charging of the target Tg with the electric power will be stopped once. Then, the substrate Wf on which the film has been formed is recovered from the stage 2, and the next substrate Wf will be transferred to the stage 2 so that the film-formation can be performed in the above-mentioned procedures. At the time of this kind of replacement of the substrates Wf, the regulation controller Co does not stop the circulation of the first refrigerant and the second refrigerant by both the first and the second chiller units Cr₁, Cr₂, respectively. Therefore, before starting the sputtering on the next substrate Wf, the surface temperature of the target Tg will be equivalent to the temperature of the first refrigerant, and the panel surface 62 of the cooling panel 6 will be equivalent to the temperature of the second refrigerant.

According to the above-mentioned embodiment, at least during the time when the target Tg receives radiant heat from the plasma, if the temperature of the first refrigerant is kept at a temperature below 263K, the number of fine particles that will be adhered to the surface of the substrate Wf immediately after the film has been formed thereon can be restrained to the best extent possible without particularly lowering the electric power to be charged to the target Tg. The above-mentioned practice becomes particularly effective when a pyrocarbon target is used as the carbon target Tg. In addition, since control is made such that the sum of the temperature of the first refrigerant to be supplied to the target Tg and the temperature of the second refrigerant to be supplied to the cooling panel 6 becomes a temperature within the range of 370K and 590K, the number of fine particles that will be adhered to the surface of the substrate Wf immediately after the film has been formed thereon can still further be restrained to the best extent possible.

In order to confirm the above-mentioned effect, the following experiments were performed by using the above-mentioned sputtering apparatus SM. In other words, the substrate Wf was silicon wafer of 300 mm in diameter, and the target 2 was made of carbon of Φ400 mm in diameter, and the above-mentioned sputtering apparatus SM was used to form a carbon film on the substrate Wf. As the sputtering conditions, the distance between the target Tg and the substrate Wf was set to 60 mm, the electric power to be charged by the sputtering power Ps was 2 kW, the sputtering time was set to 60 sec. In addition, argon gas was used as the sputtering gas and, during sputtering, the partial pressure of the sputtering gas was made to be 0.1 Pa. Then, during the time when the target is charged with electric power (i.e., during the time when the target Tg receives radiant heat from the plasma), the temperature of the first refrigerant to be supplied to the backing plate Bp was set to 291K (the temperature of supplying the backing plate with cooling water by an ordinary sputtering apparatus: 18° C.), 273K, 263K, 253K and 243K, respectively. The number of particles that has been adhered to the substrate Wf after film formation was measured. The number of the particles was measured by using a known particle counter. By the way, in these experiments, the supply of the second refrigerant to the cooling panel 6 remained stopped.

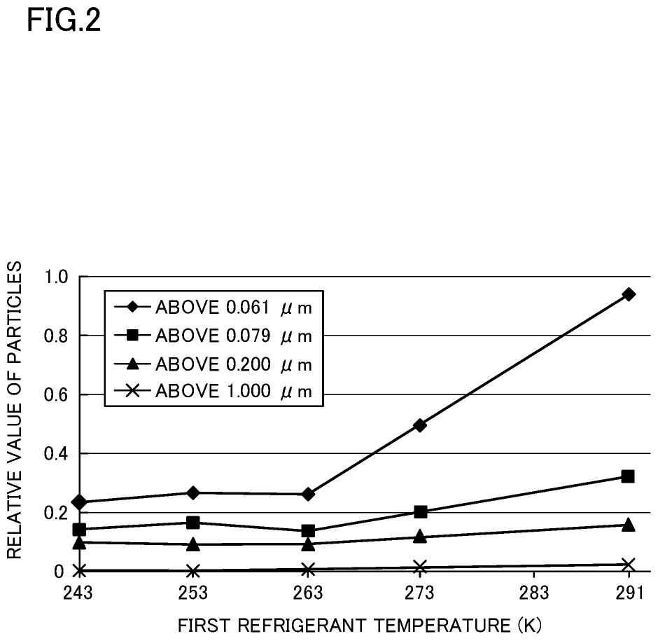

FIG. 2 is a graph to show the changes in the number of particles in relation to the temperature of the first refrigerant. In FIG. 2, —567 —shows the size above 0.061 μm, —▪—shows the size above 0.079 μm, —▴—shows the size above 0.200 μm, and —X—shows the size above 1.000 μm. According to the above, by making the temperature of the first refrigerant below 263K, it can be seen that the number of the particles can be restrained smaller in number without relation to the size.

Next, by using the above-mentioned sputtering apparatus SM, carbon films were formed on the same sputtering conditions. In these experiments, the temperature of the first refrigerant was fixed at 263K, and the temperature of the second refrigerant was appropriately changed within a range of predetermined temperatures of 50K and 350K. By way of a comparative experiment, the temperature of the first refrigerant was fixed at 291K and similarly the temperature of the second refrigerant was appropriately changed within a range of predetermined temperatures of 50K and 350K.

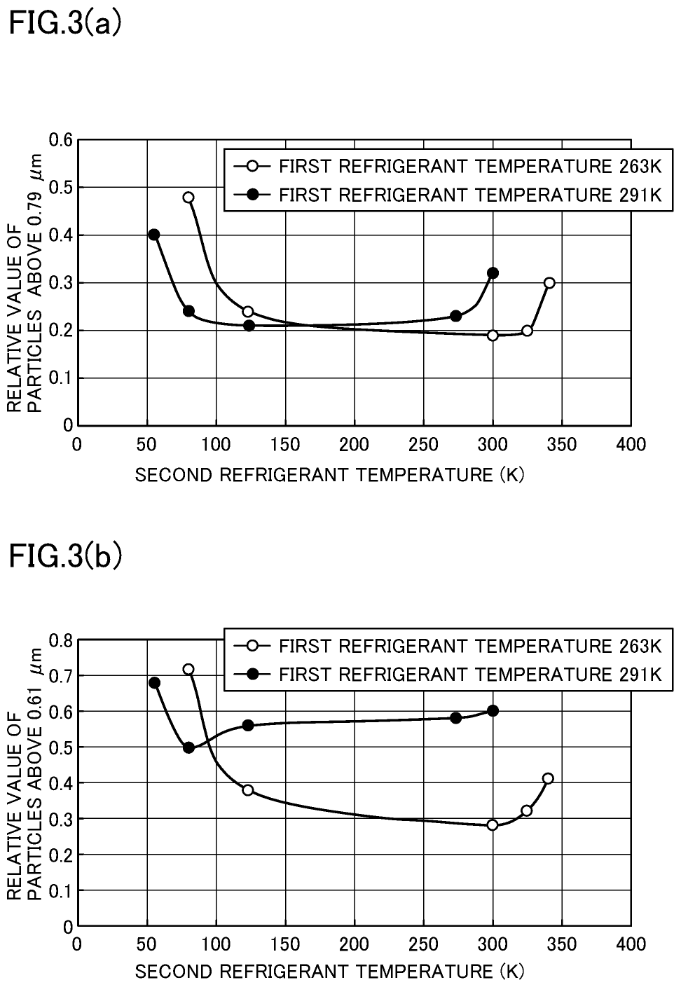

FIG. 3(a) is a graph to show the change in the number of particles above 0.79 μm in relation to the temperature of the second refrigerant, and FIG. 3(b) is a graph to show the change in the number of particles above 0.61 μm. In the figure, —◯—is the result when the temperature of the first refrigerant was made to be 263K, and —●—is the result when the temperature of the first refrigerant was made to be 291K. According to these results, it can be seen that the number of particles can be made smaller when the target Tg is cooled, during sputtering, by supplying the refrigerant of a temperature (263K) that is extremely lower than the temperature (291K) of the cooling water used in an ordinary sputtering apparatus. In addition, in either of the cases in which the temperature of the first refrigerant was 263K and 291K, if the temperature of the second refrigerant was out of the predetermined range (range of 120K and 325K), it can be seen that the number of particles to get adhered to the substrate Wf after the film has just been formed thereon increases, and that the number of particles smaller in size extremely increases.

Descriptions have so far been made of an embodiment of this invention, but this invention shall not be limited to the above. Within a range in which the technical idea of this invention is not deviated, this invention may be appropriately modified. In the above-mentioned embodiment, a description was made of an example in which the cooling body was constituted by a cooling panel 6 that is disposed in the exhaust gas inlet 15 of the exhaust space part 5 so that the carbon particles contained in the exhaust gas can also be adsorbed. However, as long as an arrangement is made that, within a vacuum chamber 1, cooling is made by a second refrigerant to a predetermined temperature to thereby adsorb to, and hold on, an adsorbent the carbon particles that are kept suspended in the vacuum chamber, it is not necessary to limit the shape (i.e., it is not necessary to be formed into a panel shape) and the location of disposition need not be limited to those as mentioned above. By the way, in case the deposition-preventive plate 3 is formed by a cooling body, it is preferable to keep the distance between the substrate Wf and the deposition-preventive plate 3 above 10 mm so that the substrate Wf is not cooled by radiation by the deposition-preventive plate.

### EXPLANATION OF MARKS

Co regulation controller (temperature control means)

Cr₁ first chiller unit (first refrigerant supply means)

Cr₂ second chiller unit (second refrigerant supply means)

SM sputtering apparatus

Tg target

Vp vacuum pump

Wf substrate (object on which a film is formed, also referred to as “film-forming object”)

1 vacuum chamber

3 deposition-preventive plate

4 gas introduction means

6 cooling panel (cooling body)

1. A sputtering method of forming a carbon film, comprising:
disposing a carbon target and a film-forming object inside a vacuum chamber;
evacuating the vacuum chamber to a predetermined pressure by a vacuum pump;
subsequently introducing a sputtering gas into the vacuum chamber;
charging the target with electric power to form a plasma atmosphere such that the target gets sputtered by the ions of the sputtering gas in the plasma, whereby carbon particles splashed from the target are caused to be adhered to, and deposited on, a surface of the film-forming object, thereby forming a carbon film,
wherein the target is cooled by heat exchanging with a first refrigerant at least during the time when the target receives radiant heat from the plasma such that the temperature of the first refrigerant is controlled to keep the temperature of the first refrigerant below 263K.

2. The sputtering method according to claim 1, in which a cooling body cooled by a second refrigerant is disposed inside the vacuum chamber, the method further comprising controlling the temperature of the second refrigerant so as to keep the temperature of the second refrigerant at a temperature within a range of 123K and 325K.

3. The sputtering method according to claim 1, in which a cooling body to be cooled by a second refrigerant is disposed inside the vacuum chamber, the method further comprising controlling the sum of the temperature of the first refrigerant and the temperature of the second refrigerant at a temperature within a range of 370K and 590K.

4. The sputtering method according to claim 2, wherein the cooling body is constituted by a cooling panel for cooling by radiation a deposition-preventive plate which encloses a space between the target and the film-forming object, both being disposed to lie opposite to each other, the cooling panel being disposed in close proximity, from an outside of the space, to the deposition-preventive plate.

5. A sputtering apparatus comprising:
a vacuum chamber having a carbon target;
a stage for holding, inside the vacuum chamber, a film-forming object in a posture to lie opposite to the target;
a deposition-preventive plate for enclosing a space between the target and the stage;
a gas introduction means for introducing a sputtering gas into the vacuum chamber in a vacuum atmosphere;
a power supply for charging the target with electric power; and
a first refrigerant supply means for supplying the first refrigerant to keep the target at a predetermined temperature by heat exchanging with the first refrigerant at least during the time when the target receives radiant heat from a plasma;
wherein the first refrigerant supply means controls the temperature of the first refrigerant to keep the temperature of the first refrigerant below 263K.

6. The sputtering apparatus according to claim 5, further comprising: a cooling panel disposed, from an outside of the space, close to the deposition-preventive plate; and a second refrigerant supply means for supplying the cooling panel with a second refrigerant,
wherein the second refrigerant supply means controls the temperature of the second refrigerant to a temperature within a range of 123K and 325K.

7. The sputtering apparatus according to claim 5, further comprising: a cooling panel disposed close, from an outside of the space, to the deposition-preventive plate; and a second refrigerant supply means for supplying the cooling panel with a second refrigerant,
the sputtering apparatus further comprising a temperature control means for controlling the temperature such that a sum of the temperature of the first refrigerant and the temperature of the second refrigerant becomes a temperature of a range of 370K and 590K.
